(19) United States
(12) Patent Application Publication
(10) Pub. No.: US 2007/0177702 A1
(43) Pub. Date: Aug. 2, 2007

(54) Receiving data over channels with intersymbol interference

(76) Inventors: Anthony Fraser Sanders, Haar (DE); Matthias Schobinger, Munchen (DE); Edoardo Prete, Munchen (DE); Norbert Neurohr, Neuried (DE); Johannes Sturm, Villach (AT); Eva Tatschl-Unterberger, Villach (AT); Nicola Dadalt, Villach (AT); Daniele Gardellini, Villach (AT)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/338,176

(22) Filed: Jan. 23, 2006

(51) Int. Cl. H03D 3/24

(52) U.S. Cl. 375/375

(57) ABSTRACT

A method of receiving data includes sampling the data at data sampling points to obtain data samples corresponding to information contained in the data, and sampling the data at intermediate sampling points between the data sampling points to obtain intermediate samples. The data is corrected at at least one intermediate sampling point of the intermediate sampling points depending on at least one of a previous data sample sampled at a data sampling point preceding the at least one intermediate sampling point and a previous intermediate sample sampled at a data sampling point preceding the at least one intermediate sampling point.

### BACKGROUND

In data transmission systems, data is typically encoded by a transmitter and sent over a channel (e.g., a copper line or a chip-to-chip connection) to be received by a receiver at the far end of the channel. In digital systems, the signal received over the channel is sampled according to a sampling clock to generate sampled data, and the sampled data is further processed in order to reconstruct the data sent by the transmitter. This sampling clock should correspond to a transmitter clock used in the transmitter for encoding and sending the data.

In principle, it is possible to transmit the transmitter clock together with the encoded data and to use the transmitted transmitter clock at the receiver as the sampling clock for sampling the received signal. However, in modem high-speed communication systems, the transmitter clock itself is typically not transmitted via the channel, but the sampling clock is reconstructed from the received signal. The process of reconstructing the sampling clock and sampling the received data with the reconstructed sampling clock in order to reconstruct the sent data is known as clock and data recovery (CDR).

Example methods and apparatuses for clock and data recovery are described in S. I. Ahmed, Tad A. Kwasniewski, “Overview Of Oversampling Clock and Data Recovery Circuits”, proceedings of CCECE/CCGEI, IEEE, May 2005, or in Behzad Razavi, “Challenges in the Design of High-Speed Clock and Data Recovery Circuits”, IEEE Communications Magazine, August 2002, pages 94-101, both of which are incorporated herein by reference.

In particular, clock recovery often employs a phase-locked loop (PLL) that is controlled by a phase detector detecting whether the phase of a sampling clock generated by the PLL is aligned with the phase of the received signal. A phase detector which is comparatively easy to implement and which is suitable for high-speed applications is the Alexander-type phase detector which is described in detail in the above-cited Razavi reference. The principle of this phase detector will be described below with reference to FIGS. 4A-4C.

FIGS. 4A-4C each illustrate an example signal al, which in the illustrated example is a voltage (V) signal, over time. The signal al may be a single-ended signal, or the signal may be a differential signal, in which case the signal comprises components a1, a2, and the received signal value corresponds to a1-a2. The signals (i.e., a1 and a2 in FIGS. 4A-4C are depicted as “ideal” signals, i.e. without noise and without intersymbol interferences, which is discussed below).

The signal a1 (or the differential signal comprising a1 and a2) is, in the illustrated example, a binary signal, wherein three bits are depicted with values of 1, −1 and again 1. A value of 1 may correspond to a logic 1 (i.e., a set bit) whereas a value of −1 may correspond to logic 0 (i.e., a cleared bit).

At the receiver, the signal a1 is sampled at data sampling points D1, D2, D3 to generate data samples which are used to reconstruct the information contained in the signal. Furthermore, the signal a1 is sampled at intermediate or transition sampling points T1, T2, T3 which generally are positioned between data sampling points D1, D2, D3.

In FIG. 4A, the data sampling points D1, D2, D3 and the transition sampling points T1, T2, T3 are at positions which, in many cases, may be regarded as ideal positions, such that a corresponding phase-locked loop would be in a locked state. In particular, the data sampling points D1, D2, D3 are located in the middle of each bit, whereas the transition sampling points are at the transitions between one bit and the next. In the case of FIG. 4A, at the data sampling points D1 and D3 a value of “1” would be sampled, at the data sampling points D2 a value of “−1” would be sampled, and at the transition sampling points T1, T2, T3 a zero value (i.e., a value at the threshold value of a slicer deciding whether a sampled value corresponds to a +1 or a −1) would be sampled.

In the case of FIG. 4B, the data sampling points D1, D2, D3 and the transition sampling points T1, T2, T3 lag compared to the sampling points of FIG. 4A (i.e., the signal a1 is sampled later than in the case of FIG. 4A). In this case, at D1 a value of 1 is sampled, at T1 and D2 a value of −1 is sampled, at T2 and T3 a value of +1 is sampled, and at T3 again a value of −1 is sampled. Therefore, when the sampling points lag with respect to the “ideal” sampling points of FIG. 4A, in a data transition (as in the examples from 1 to −1 and vice versa), the value sampled at a transition sampling point is equal to the value sampled at the data sampling point following the transition sampling point and different from the value sampled at the data sampling point preceding the transition sampling point.

In FIG. 4C, the opposite situation compared to FIG. 4B is illustrated. Here, the data sampling points and the transition sampling points are ahead of the data sampling points and transition sampling points of FIG. 4A. In this case, at D1 and T1 a value of 1 is sampled, at D2 and T2 a value of −1 is sampled, and at D3 and T3 again a value of +1 is sampled. Therefore, in this case, a transition of the signal, the value sampled at a transition sampling point corresponds to the value sampled at the data sampling point preceding the transition sampling point and is different from the value sampled at the data sampling point following the transition sampling point.

Therefore, by comparing the value sampled at a transition sampling point with the value sampled at data sampling points before and after this transition sampling point, a direction in which the sampling phase has to be corrected can be ascertained. This direction information can be used for adjusting an oscillator in a phase-locked loop which generates a clock signal determining the data sampling points and/or transition sampling points.

In case of no data transition (e.g., two consecutive bits having the value 1), the corresponding samples at the data sampling points have the same value as the value sampled at the transition sampling point between the data sampling points. In this case, no information regarding the phase can be ascertained.

As already indicated above, the signals depicted in FIGS. 4A-4C are ideal signals. In reality, besides noise, intersymbol interference occurs in particular at high data rates. Intersymbol interference is caused by distortion of the signal when sending it via the channel.

FIG. 5 illustrates an example impulse response of the channel over time, wherein the impulse response is basically the signal which is received when a short rectangular pulse is sent. As illustrated in FIG. 5, the pulse, which in a case without distortion, would be present at data sampling point D1 in FIG. 5, is broadened significantly, in particular in the direction after sampling point D1. The broadening is significantly broader than the unit interval (UI) (i.e., the time between two data sampling points). Therefore, a part of the pulse is still present at data sampling points D2, D3 and even D4 and also at the transition sampling points, of which only T1 is illustrated. Therefore, the signal actually sampled at a given sampling point (data sampling point or transition sampling point) is a superposition of the pulse intended to be received at this data sampling point and a number of pulses before this pulse or even after this pulse. In the example of FIG. 5, contributions of the illustrated pulse would be present at data sampling points D2, D3 and D4. These contributions referred to as postcursors. As the sign of the pulses, and, in the case of non-binary transmission, also their amplitude, depend on the value of the respective sent bit, the sum of all the postcursors at a given sampling point is not constant, but depends on the values of the preceding bits.

The effect of this may be visualized in an eye diagram, which is schematically illustrated in FIG. 6. The eye diagram illustrates an overlay of a large number of received bits (similar to a signal viewed by an oscilloscope) and therefore gives an impression of the possible values which may be received. The eye diagram of FIG. 6 is only a schematic view and in particular does not take the shape of the pulse response of FIG. 5 (i.e., the fact that the influence of a preceding bit is larger at the beginning of a bit than at the end of a bit) into account. A more realistic eye diagram is for example illustrated in the above-cited Ahmed and Kwasniewski reference.

In particular, compared to FIGS. 4A and 4C all the lines are broadened as there is a plurality of possibilities how the postcursors may combine with the actual value corresponding to the momentarily received bit to form the signal. In FIG. 6, the possible values without data transition are indicated at 25, whereas the possible values at data transitions are indicated at 26.

This effect is known as intersymbol interference (ISI).

As can be seen from FIG. 6, a first effect of the intersymbol interference is that a distance x, referred to as vertical eye opening, decreases. In case of very strong intersymbol interference, x may be reduced to zero resulting in data sampled at the data sampling points having a high bit error rate. This problem, as can be easily understood from FIG. 5, increases with increased data rate since the size of the unit interval UI decreases and therefore the influence of the postcursors increases. Furthermore, the effect also increases with increasing channel length, because distortion of the signal and therefore the width of the pulse illustrated in FIG. 5 increases.

Various methods are known to at least partially correct the influence of postcursors, such as maximum likelihood estimation and decision-feedback equalization. Of these methods, decision-feedback equalization is particularly suited for high-speed applications.

The principle of decision-feedback equalization is explained below with reference to FIG. 7, whereas a more detailed discussion may be found in N. Neurohr et al., “Adaptive Decision-Feedback Equalization For Band-Limited High-Speed Serial Links”, Proceedings of ISCAS 2005, pages 924-927, which is herein incorporated by reference.

In an example decision-feedback equalizer (DFE) illustrated in FIG. 7, a received signal r is fed to a first input of an adder 21. A correction signal cd is fed to a second input of adder 21. A resulting sum signal y is fed from adder 21 to a slicer 22. Slicer 22 provides data symbols d which, in the case of no bit errors, corresponds to the data symbols used for generating the received signal r.

The data symbols d are provided from slicer 22 for further use and additionally fed back from slicer 22 to a delay element 23 which delays the data symbols for one unit interval. The delay element 23 may, for example, be realized by a flip-flop or any other suitable register. The delayed data symbols are then multiplied by a factor c in a multiplier 24 to form the correction signal cd. In adder 21, c will usually be a negative value such that a value based on the preceding bit value is subtracted from the received signal r. The effect of the first precursor (at D2 in FIG. 5) can be compensated with a DFE as illustrated in FIG. 7. Methods for determining the coefficient c are described in the above-referenced Neurohr et al reference.

In the case where more precursors have to be compensated, the DFE may be expanded accordingly to subtract a number of previously received values, weighted with respective coefficients, from the received signal.

Referring to FIG. 6, the problem of the vertical eye opening diminishing at the data sampling points D1, D2, D3 etc. is not the only problem related to strong intersymbol interference. In particular, as illustrated in FIG. 6, the transition samples sampled at the transition sampling points T1, T2, T3, assume more or less random values in a certain region around the “ideal” sampling point illustrated in FIG. 6, which makes the transition samples basically unusable for the clock recovery as explained with reference to FIGS. 4A-4C.

A known solution for this problem is to obtain the transition samples from the received signal after boosting (i.e., linear filtering) the received signal. While such boosting is typically not usable for the signal sampled at the data sampling points to recover the sent data because it would lead to an unacceptable rate of bit errors, the clock recovery is generally more error-tolerant and therefore can be performed using boosting. On the other hand, in modem high-speed chip architectures such as chip-to-chip connections with a bit rate of 3 Gbits/s and higher, the power consumption and thus heat generated by boosting would be unacceptably high.

### SUMMARY

One aspect of the present invention provides a method for receiving data. The method includes sampling the data at data sampling points to obtain data samples corresponding to information contained in the data. The method includes sampling the data at intermediate sampling points between the data sampling points to obtain intermediate samples. The method includes correcting the data at at least one intermediate sampling point of the intermediate sampling points depending on at least one of a previous data sample sampled at a data sampling point preceding the at least one intermediate sampling point and a previous intermediate sample sampled at a data sampling point preceding the at least one intermediate sampling point.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a circuit diagram of one embodiment of the present invention.

FIG. 2 is a circuit diagram of one embodiment of the present invention.

FIG. 3 is a circuit diagram of one embodiment of the present invention.

FIGS. 4A-4C are diagrams of signals with data sampling points and transition sampling points.

FIG. 5 is a diagram illustrating an impulse response of an exemplary channel.

FIG. 6 is a schematic eye diagram.

FIG. 7 is a circuit diagram of a decision-feedback equalizer.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One embodiment provides a method and an apparatus for receiving data over channels with intersymbol interference which are usable at high bit rate, have acceptable power consumption, and allow for a reliable clock and data recovery using intermediate or transition samples.

One embodiment employs principles of decision-feedback equalization to intermediate samples taken between data samples. Additionally, decision-feedback equalization may also be performed for the data samples, which are used to reconstruct sent data from the received data.

One embodiment of a method of receiving data includes the data at data sampling points to generate data samples; sampling the data at intermediate sampling points between the data sampling points to obtain intermediate samples; and correcting the data at at least one intermediate sampling point of the intermediate sampling points depending on at least one of a previous data sample sampled at a data sampling point preceding the at least one intermediate sampling point and a previous intermediate sample sampled at an intermediate sampling point preceding the at least one intermediate sampling point.

In particular, the data samples may be used to determine received data values, while the intermediate samples, possibly together with the data samples, may be used for adjusting or adapting the data sampling points and/or the intermediate sampling points. In one embodiment, the intermediate sampling points are positioned in the middle between two respective data sampling points. In one embodiment, once the intermediate sampling points have been adjusted, the intermediate sampling points are positioned at transition points where the received data may change its value depending on data values used for generating the data.

The correction may be performed by multiplying the at least one of a previous data sample and a previous intermediate sample with a corresponding coefficient and subtracting the result from the data at the at least one intermediate sampling point. The number of previous data samples and/or previous intermediate samples used for correcting generally depends on the strength of intersymbol interferences on the channel over which the data is received. However, in most cases at least the data sample sampled at the data sampling point immediately preceding the at least one intermediate sampling point is used.

Additionally, one embodiment of a method correcting the data at the data sampling points depending on at least one of a further previous data sample and a further previous intermediate sample. Therefore, the principle of decision-feedback equalization may also be used for correcting the data at the data sampling points to improve the quality of the obtained data samples.

Depending on the bit rate of the data, it may be advantageous to implement the correcting step by generating at least two possible corrected data values and choosing a corrected data value as the data at the at least one intermediate sampling point depending on the at least one of a previous data sample and a previous intermediate sample.

In one embodiment, a feedback path corrects the data at the intermediate points, in which the at least one of a data sample and an intermediate sample may be delayed and then multiplied with a coefficient and added to the data stream at the intermediate points. In a similar manner, for correcting the data at the data sampling points, at least one of a data sample and an intermediate sample may be delayed and multiplied with a coefficient. The delaying for the two corrections may be implemented as a common delay line or as separate delay lines.

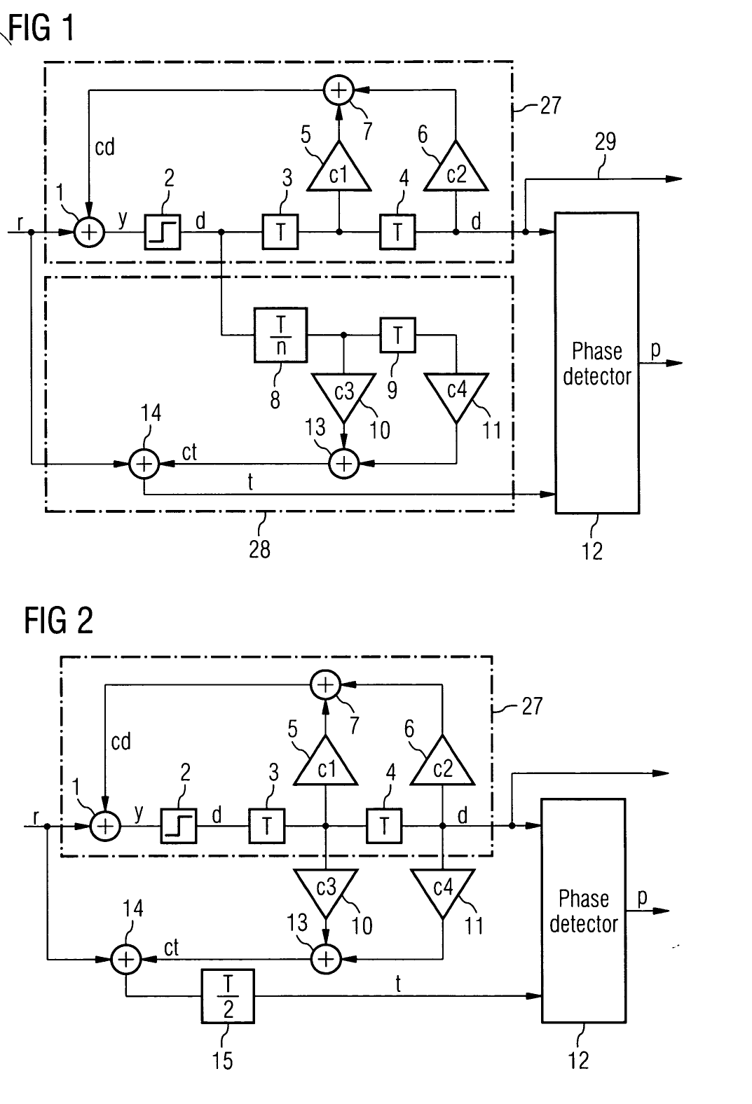

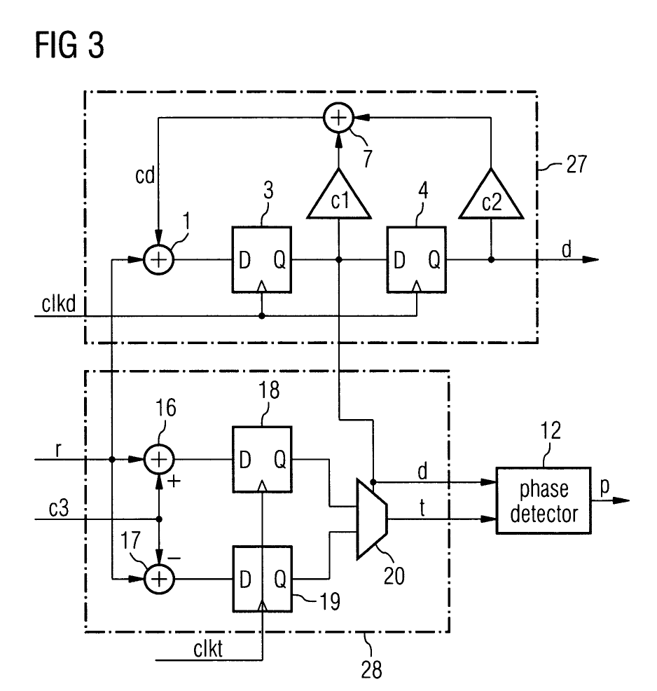

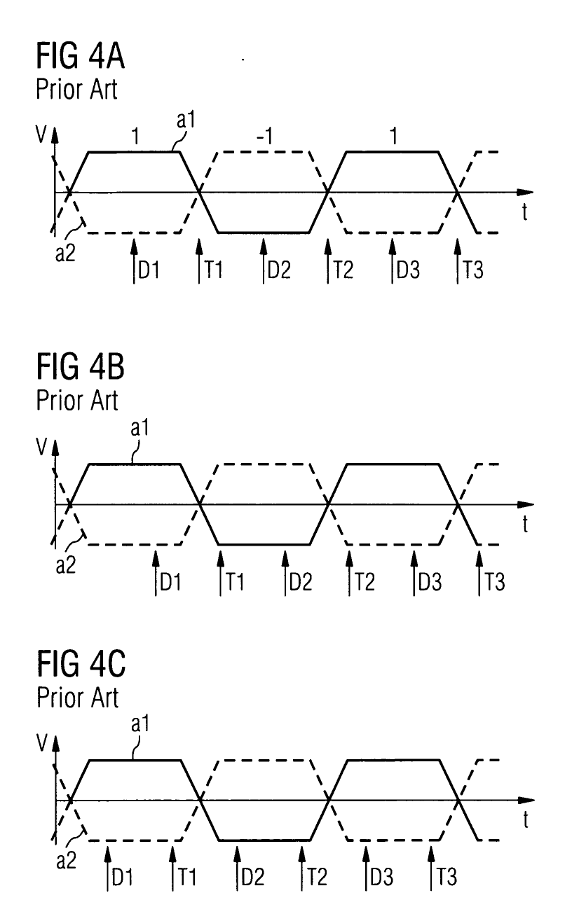

FIG. 1 illustrates one embodiment of a circuit according to the present invention. A data signal r is received over a channel (e.g., a chip-to-chip connection or a copper line). Data signal is fed to a first input of an adder 1 and to a first input of an adder 14. A data correction signal cd is applied to a second input of the adder 1. A sum signal y, which is a sum of the received signal r and the data correction signal cd, is fed to a slicer 2. Slicer 2 provides data symbols d. In the case of a binary transmission, similar to as described with reference to FIGS. 4A-4C in the Background section, slicer 2 may output a data symbol d=+1 for y>0 and d=−1 for y<0. In particular, as described later with reference to FIG. 3, in this case slicer 2 may be implemented comprising a flip-flop. In case of multi-level data transmission (i.e., a data transmission where more than two possible data symbols may be output by the slicer 2) the slicer compares the sum signal y to a number of thresholds and thus decides which data symbol to output.

The data symbols d are fed to a delay element 3 which delays the data symbols for one unit interval (i.e., the time between two data symbols or samples output by the slicer 2). Slicer 2 is controlled by a data sampling clock to sample data at predetermined data sampling points.

The output of delay element 3 is connected with the input of a second delay element 4 which again delays the data symbols by one unit interval. Furthermore, the output of first delay element 3 is connected with the input of a first multiplier 5 which multiplies the data symbols output by first delay element 3 by a first coefficient c1. The output of second delay element 4 is connected with an input of a second multiplier 6 which multiplies the data symbols output by the second delay element with a second coefficient c2. Furthermore, the data symbols d output from second delay element 4 are fed to a phase detector 12 and are provided on a line 29 for further processing.

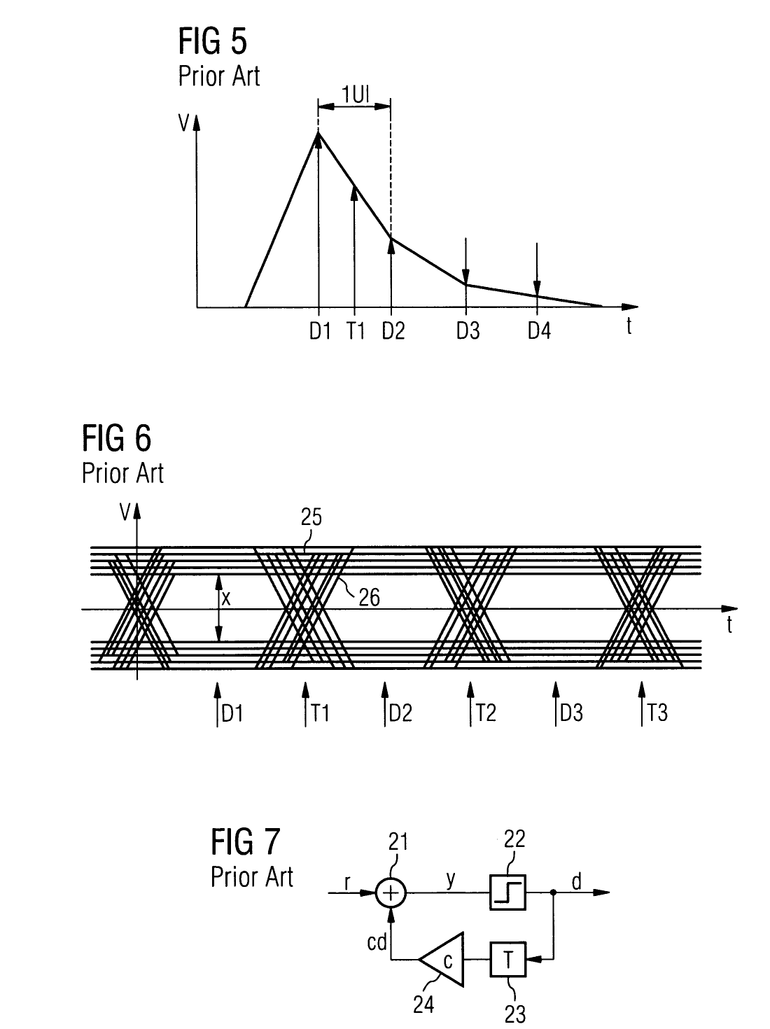

The outputs of first multiplier 5 and second multiplier 6 are added at an adder 7 to form the data correction signal cd. The part of the circuit of FIG. 1 described above, generally indicated at 27 in FIG. 1, forms a decision-feedback equalizer (DFE) similar in many ways to the one discussed in the background section with reference to FIG. 7. However, decision-feedback equalizer 27 employs two previous data samples for correcting the received data r. In particular, if k denotes the data sampling points (i.e., k=1, 2, 3, . . . ) the correction of the received signal in order to obtain the data symbols d may be described as
yₖ=rₖ+c1·dₖ₋₁+c2·dₖ₋₂ (1)
wherein yₖ is the sum signal y at the k-th data sampling point, rₖ is the received data at the k-th data sampling point, dₖ₋is the k−1-th data symbol, and dₖ₋₂ is the (k−2)-th data sample. In order to obtain good correction of the postcursors, for the impulse response already described with reference to FIG. 5, c1 would be the negative of the pulse response at data sampling point D2 in FIG. 5 and c2 would be the negative of the impulse response at data sampling point D3 in FIG. 5. Therefore, with DFE 27, the influence of the first and second postcursor may be corrected.

In one embodiment, instead of choosing negative coefficients c1, c2, the coefficients c1, c2 may be positive and the adder 1 may be replaced by a subtractor which subtracts the data correction signal cd from the received data r.

As mentioned above, the received data signal r is fed to a first input of an adder 14. Furthermore, the data symbols d are fed to a third delay element 8 which, however, does not delay the data symbols by a whole unit interval, but by a fraction of a unit interval, symbolized by T/n in FIG. 1. An output of third delay element 8 is connected with an input of a third multiplier 10 and an input of a fourth delay element 9. An output of fourth delay element 9 is connected with an input of a fourth multiplier 11.

Third multiplier 10 multiplies the data symbols output by third delay element 8 by a third coefficient c3 and fourth multiplier 11 multiplies the data symbols output from forth delay element 9 by a forth coefficient c4. The outputs of third multiplier 10 and fourth multiplier 11 are added at an adder 13 to form a transition correction signal ct, which is fed to a second input of adder 14. A signal t is output from adder 14 and fed to phase detector 12.

In particular, the value of the signal t at 1/n UI after the k-th data sampling point may be expressed as

$${t}_{k + \frac{1}{n}} = {r}_{k + \frac{1}{n}} + c 3 \cdot {d}_{k} + c 4 \cdot {d}_{k - 1} \qquad ( 2 )$$

For many applications, n will be equal to 2 so that the signal will be corrected at the points exactly between the data sampling points (i.e., that transition sampling points T1, T2, T3 of FIGS. 4-6). At these transmission sampling points, in the embodiment illustrated the signal t is sampled and processed by a slicer in phase detector 12 to provide a phase correction signal p for the data sampling clock and the transmission sampling clock as described in detail above with reference to FIGS. 4A-4C. Through appropriate choice of the coefficients c3 and c4, the signal t may be corrected at the transmission sampling points such that the influence of the two data samples immediately preceding the transition sample may be corrected. In particular, the coefficients c3 and c4, in case of n=2, are preferably chosen such that the signal

$${t}_{k + \frac{1}{n}}$$

is as close to 0 as possible in the case of data transitions.

For some applications it may be advantageous to chose n≠2, for example n=3 or n=1.5 (n is not restricted to integers). Such a choice may in particular be useful if other samples than the transition samples are needed for a particular application.

Elements 8, 9, 10, 11, 13 and 14 form a DFE-like correction loop 28 which, however, employs slicer 2 of DFE 27. In principle, it is possible to implement a plurality of correction loops 28 for different values of n in case a plurality of samples besides the actual data samples or data symbols d are desired, for example for phase detection.

The circuit of FIG. 27 is implemented in a mixed signal approach (i.e., the received data r is digitized only after correction with the data correction signal cd in slicer 2 and after correction with the transition correction signal ct in the phase detector 12). In one embodiment, a received data signal r is digitized with an analog-to-digital converter before correction and then the functionality of the circuit of FIG. 1 is implemented in a completely digital manner (e.g., by programming a digital signal processor (DSP) accordingly).

FIG. 2 illustrated one embodiment of a circuit according to the present invention which is a modification of the circuit embodiment of FIG. 1. In particular, the DFE 27 of FIG. 2 is substantially the same as the DFE 27 of FIG. 1 and shall therefore not be described again. In particular, the above equation (1) also applies to the DFE 27 of FIG. 2.

In contrast to the circuit of FIG. 1, in the circuit of FIG. 2, the delay elements 3 and 4 of the DFE 27 are also employed for forming a transition correction signal ct. To achieve this, the delay elements 3 and 4 output the same sampled data symbol d over the whole of the respective unit interval. This functionality is, for example, present if flip-flops or similar registers are used as delay elements, as described below with reference to FIG. 3.

As illustrated in FIG. 2, an output of first delay element 3 is connected with an input of a multiplier 10 for multiplying the data symbols output from first delay element 3 by a third coefficient c3. In a similar manner, an output of second delay element 4 is connected with an input of a fourth multiplier 11 for multiplying the data symbols output from second delay element 4 by a fourth coefficient c4. The outputs of third multiplier 10 and fourth multiplier 11 are added in adder 13 to form the transition correction signal ct which is added to the received data signal r at an adder 14. An output of adder 14 is connected to phase detector 12 via a delay element 15 which delays a transition signal t by half a unit interval. Because of delay element 15, the transition samples may be sampled in phase detector 12 at the same points in time as the data symbols d are samples. However, in one embodiment, delay element 15 is omitted and the signal t is sampled in the phase detector 12 at the appropriate transition sampling points. The correction obtained for the signal t is the same as the one obtained by the embodiment of FIG. 1.

The embodiment of FIG. 2 employs fewer delay elements than the embodiment of FIG. 1, which saves chip space. On the other hand, the embodiment of FIG. 1 is more flexible.

In some cases, the feedback path for feeding back the transition correction signal ct to adder 14 may be time-critical. This in particular holds true for the path of FIG. 1 comprising third delay element 8, multiplier 10 and adder 13, because in this case the feedback is performed within a fraction of a unit interval, for n=2 half a unit interval. For high-speed connections, such a feedback may even be impossible. For these cases, another embodiment of a circuit according to the present invention is illustrated in FIG. 3, which can implement such a feedback even for high speed connections.

The DFE 27 of the circuit embodiment illustrated in FIG. 3 is designed as the DFEs 27 in FIGS. 1 and 2. However, in FIG. 3, an exemplary implementation of delay elements 3 and 4 as flip-flops is illustrated. In particular, flip-flops 3 and 4 are clocked by a data sampling clock clkd such that at each data sampling point (similar to the data sampling points D1, D2, . . . in FIGS. 4-6) the signal at a data input D of the respective flip-flop 3 or 4 is sampled, and a corresponding value is output at a respective output Q. The slicer 2 may be omitted in this case if the flip-flop 3 itself is designed to act as a slicer. In particular, in the case of binary signals, flip-flop 3 may output a value 1 for a data symbol if the signal at its input D is greater than 0 and a value of −1 if an input is smaller than 0. The same functionality applies to flip-flop 4 corresponding to a second delay element.

The correction circuit 28 in the embodiment of FIG. 3 is implemented using a feed-forward technique. In particular, the received data signal r is fed to a first input of an adder 16 and to a positive input of a subtractor 17. Furthermore, a signal value corresponding to the coefficient c3 is fed to a second input of adder 16 and to a negative input of subtractor 17. Therefore, adder 16 outputs a value r+c3, whereas subtractor 17 outputs a value r−c3. Compared to FIG. 1, this corresponds to the two possible values for the signal t in case the elements 9 and 11 are omitted, because the data symbols output by third delay element 8 are either +1 or −1 and therefore, ct is either +c3 or −c3.

An output of adder 16 is connected to an input D of a flip-flop 18, whereas an output of subtractor 17 is connected to an input D of a flip-flop 19. Flip-flop 18 and flip-flop 19 are clocked with a transition sampling clock clkt, such that they sample the signal at their respective inputs D at the transition sampling points T1, T2, T3 of FIGS. 4-6. Consequently, the transition sampling clock clkt is delayed by half a period (i.e., half a unit interval) or 180 degrees with respect to data sampling clock clkd. Such two clock signals with a phase difference of 180 degrees may be generated by a quadrature oscillator, or the signal clkt may be obtained by inverting the signal clkd which corresponds to a 180 degree shift. In another embodiment, a clock signal having a duty cycle of basically 50% is employed and the rising clock edges are employed as the data sampling points and the falling edges are employed as intermediate or transition sampling points.

An output Q of flip-flop 18 is connected to a first input of a multiplexer 20, and an output Q of flip-flop 19 is connected to a second input of multiplexer 20. Depending on the data symbol output from flip-flop 3, either the output of flip-flop 18 or the output of flip-flop 19 is used as signal t. In particular, when the data symbol output by flip-flop 3 is +1, the output from flip-flop 18, (i.e., r+c3) is used, while when the data symbol output from flip-flop 3 is equal to −1, the output of flip-flop 19, (i.e., r−c3) is used. Therefore, the same correction to form the signal t is obtained as by using the branch comprising elements 8, 10 and 13 of FIG. 1. As in the circuit embodiments of FIGS. 1 and 2, in the circuit embodiment of FIG. 3, the data symbols d and the transmission signal t are fed to a phase detector 12.

The correction circuit 28 of the embodiment of FIG. 3 provides a correction substantially equal to the one provided by the branch comprising elements 8, 10 of FIG. 1. In many cases this correction is sufficient since, as explained in the Background section with reference to FIG. 5, the data symbol immediately preceding the transition sample has the greatest influence on the transition sample. In case further correction is needed, a further branch corresponding to the one comprising elements 9 and 11 of FIG. 1 may be added, which may be implemented either in a manner similar to the embodiments of FIGS. 1 or 2, or also with a look-ahead architecture like the circuit embodiments illustrated in FIG. 3.

As stated above, the delay elements 3, 4, 8, 9 and 15 of FIGS. 1 and 2 may be implemented as flip-flops, as illustrated in FIG. 3. The adders (or subtractors) of the embodiments illustrated may be implemented by time continuous comparators, a switched capacitor charge sharing or as a current summing point. In principle, any suitable mechanism for adding two values is possible.

The present invention may be implemented using either a full rate or a half rate clock architecture, (i.e., both rising and falling clock edges or only one of the two may be used). The flip-flop or registers illustrated can use any suitable form of signaling, for example full swing CMOS signaling or small swing CML (current mode logic).

Furthermore, in the embodiments presented both the data correction signal cd and the transition corrector signal ct are formed based on previous data samples or data symbols d. However, in certain embodiments, additionally or alternatively transition samples, (i.e., samples of the signal t at intermediate or transition sampling points), may be taken into account.

Embodiments of the present invention provide simple methods and apparatuses for obtaining corrected transition samples or other additional intermediate samples and thus allow for a correct clock and data recovery including the detection of phase wander of a clock underlying the received signal.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for receiving data, the method comprising:
sampling the data at data sampling points to obtain data samples corresponding to information contained in the data;
sampling the data at intermediate sampling points between the data sampling points to obtain intermediate samples; and
correcting the data at at least one intermediate sampling point of the intermediate sampling points depending on at least one of a previous data sample sampled at a data sampling point preceding the at least one intermediate sampling point and a previous intermediate sample sampled at a data sampling point preceding the at least one intermediate sampling point.

2. The method according to claim 1, wherein the correcting comprises:
multiplying the at least one of a previous data sample and a previous intermediate sample with a coefficient to generate an intermediate correction signal; and
combining the intermediate correction signal with the data.

3. The method according to claim 1, further comprising:
correcting the data at at least one data sampling point of the data sampling points depending on at least one of a further previous data sample sampled at a data sampling point preceding the at least one data sampling point and a further previous intermediate sample sampled at a data sampling point preceding the at least one data sampling point.

4. The method according to claim 3, wherein the further correcting comprises:
multiplying the at least one of a further previous data sample and a previous intermediate sample with a further coefficient to generate a data correction signal; and
combining the data correction signal with the data.

5. The method according to claim 4, wherein the at least one of a previous data sample and a previous intermediate sample comprises the same sample as the at least one of a further previous data sample and a further previous intermediate sample.

6. The method according to claim 4, wherein the correcting comprises:
multiplying the at least one of a previous data sample and a previous intermediate sample with a coefficient to generate an intermediate correction signal; and
combining the intermediate correction signal with the data; and
wherein the coefficient is different from the further coefficient.

7. The method according to claim 6, wherein the at least one of a further previous data sample and a further previous intermediate sample comprises a previous data sample delayed by one unit interval;
wherein the at least one of a previous data sample and a previous intermediate sample comprises a previous data sample delayed by a fraction of a unit interval, wherein the unit interval is the time between two consecutive data sampling points.

8. The method according to claim 7, wherein the fraction of a unit interval is approximately half a unit interval.

9. The method according to claim 6, wherein the at least one of a further previous data sample and a further previous intermediate sample comprises a previous data sample delayed by one unit interval, and wherein the at least one of a previous data sample and a previous intermediate sample comprises a previous data sample delayed by a unit interval, wherein the unit interval is the time between two consecutive data sampling points.

10. The method according to claim 1, wherein the correcting comprises:
calculating at least two possible corrected values for the data, and
selecting one of the at least two different corrected data values as corrected data at the at least one intermediate sampling point depending on a value of the at least one of a previous data sample and a previous intermediate sample.

11. The method according to claim 1, wherein the at least one of a previous data sample and a previous intermediate sample comprises the data sample sampled at the data sampling point immediately preceding the at least one intermediate sampling point.

12. The method according to claim 1, the method further comprising:
adapting the time position of at least one of the data sampling points and the intermediate sampling points depending on the data samples and the intermediate samples.

13. An apparatus for receiving data, the apparatus comprising:
means for sampling the data at data sampling points to obtain data samples;
means for sampling the data at intermediate sampling points between the data sampling points to obtain intermediate samples; and
means for correcting the data at at least one intermediate sampling point of the intermediate sampling points depending on at least one of a previous data sample sampled at a data sampling point preceding the at least one intermediate sampling point and a previous intermediate sample sampled at an intermediate sampling point preceding the at least one intermediate sampling point.

14. The apparatus according to claim 13, wherein the means for correcting the data comprises:
means for multiplying the at least one of a previous data sample and a previous intermediate sample with a coefficient to generate an intermediate correction signal; and
means for combining the intermediate correction signal with the data.

15. The apparatus according to claim 13, further comprising:
further means for correcting the data at at least one data sampling point of the data sampling points depending on at least one of a further previous data sample sampled at a data sampling point preceding the at least one data sampling point and a further previous intermediate sample sampled at a data sampling point preceding the at least one data sampling point.

16. The apparatus according to claim 15, wherein the further means for correcting comprises:
further means for multiplying the at least one of a further previous data sample and a previous intermediate sample with a further coefficient to generate a data correction signal; and
further means for combining the data correction signal with the data.

17. The apparatus according to claim 16, wherein the at least one of a previous data sample and a previous intermediate sample comprises the same sample as the at least one of a further previous data sample and a further previous intermediate sample.

18. The apparatus according to claim 16, wherein the means for correcting comprises:
means for multiplying the at least one of a previous data sample and a previous intermediate sample with a coefficient to generate an intermediate correction signal; and
means for combining the intermediate correction signal with the data, wherein the coefficient is different from the further coefficient.

19. The apparatus according to claim 18, wherein the at least one of a further previous data sample and a further previous intermediate comprises a previous data sample delayed by one unit interval, and wherein the at least one of a previous data symbol and a previous intermediate sample comprises a previous data sample delayed by a fraction of a unit interval defined as the time between two consecutive data sampling points.

20. The apparatus according to claim 18, wherein the at least one of a further previous data sample and a further previous intermediate sample comprises a previous data sample delayed by one unit interval, and wherein the at least one of a previous data symbol and a previous intermediate sample comprises a previous data sample delayed by a unit interval defined as the time between two consecutive data sampling points.

21. The apparatus according to claim 13, wherein the means for correcting comprises:
means for calculating at least two possible corrected values for the data; and
means for selecting one of the at least two different corrected data values as corrected data at the at least one intermediate sampling point depending on a value of the at least one of a previous data sample and a previous intermediate sample.

22. The apparatus according to claim 13, wherein the at least one of a previous data sample and a previous intermediate sample comprises the data sample sampled at the data sampling point immediately preceding the at least one intermediate sampling point.

23. The apparatus according to claim 13, further comprising:
means for adapting the time position of at least one of the data sampling points and the intermediate sampling points depending on the data samples and the intermediate samples.

24. An apparatus configured to receive data, the apparatus comprising:
a data input;
a first sampling unit clocked by a data sampling clock operatively connected to the data input and configured to sample data fed to the data input at data sampling points determined by the data sampling clock to generate data samples;
a second sampling unit clocked by an intermediate sampling clock operatively connected to the data input and configured to sample data fed to the data input at intermediate sampling points determined by the intermediate sampling clock;
a calculating unit operatively connected to at least one of the first sampling unit and the second sampling unit and configured to calculate an intermediate correction signal; and
an adder operatively connected to the data input and to the calculating unit and configured to add the intermediate correction signal to the data for correcting the data at the intermediate sampling points.

25. The apparatus according to claim 24, wherein the first sampling unit comprises at least one of a register and a slicer.

26. The apparatus according to claim 25, wherein the register comprises a flip-flop.

27. The apparatus according to claim 24, comprising:
at least one delay element operatively connected to the data input and to the calculating unit and configured to feed at least one of delayed data samples and delayed intermediate samples to the data unit.

28. The apparatus according to claim 27, comprising:
a further calculating unit operatively connected to the delay element and configured to calculate a data correction signal; and
a further adder operatively connected to the data input and to the calculating unit and configured to add the data correction signal to the data for correcting the data at the data sampling point.

29. The apparatus according to claim 27, comprising:
a further calculating unit operatively connected to a further delay element and configured to calculate a data correction signal;
the further delay element configured to feed at least one of delayed data samples and delayed intermediate samples to the further calculating unit; and
a further adder operatively connected to the data input and to the calculating unit and configured to add the data correction signal to the data for correcting the data at the data sampling point.

30. The apparatus according to claim 29, wherein the delay element is configured to delay by a fraction of a unit interval, and the further delay unit is configured to delay by a unit interval defined as the time between two adjacent data sampling points.
